(19) United States
(12) Patent Application Publication
(10) Pub. No.: US 2019/0310332 A1
(43) Pub. Date: Oct. 10, 2019

(54) MAGNETIC FIELD GRADIENT COIL ASSEMBLY WITH INTEGRATED MODULATOR AND SWITCH UNIT

(71) Applicant: KONINKLIJKE PHILIPS N.V., EINDHOVEN (NL)

(72) Inventors: CHRISTOPH LEUSSLER, HAMBURG (DE); CHRISTIAN FINDEKLEE, HAMBURG (DE)

(21) Appl. No.: 16/308,839

(22) PCT Filed: Jun. 9, 2017
(86) PCT No.: PCT/EP2017/064117

§ 371 Date: Dec. 11, 2018

(30) Foreign Application Priority Data
Jun. 16, 2016 (EP) 16174812.4

(51) Int. Cl. G01R 33/36; G01R 33/385; G01R 33/56; G01R 33/54

(52) U.S. Cl. CPC G01R 33/3664; G01R 33/3852; G01R 33/3692; G01R 33/3856; G01R 33/5608; G01R 33/543; G01R 33/3858

(57) ABSTRACT

The invention provides for a magnetic resonance imaging system (100, 200). The magnetic resonance imaging system comprises a magnet assembly (102) for generating a main magnetic field within an imaging zone (108). The magnetic resonance imaging system further comprises a magnetic field gradient coil assembly (110) for generating a spatial gradient magnetic field within the imaging zone. The magnetic field gradient coil assembly comprises at least one structural support (122). Each of the at least one structural support comprises at least one coil element (500). The magnetic resonance imaging system further comprises a gradient coil power supply (112) for supplying current to the magnetic field gradient coil assembly. The gradient coil power supply is a switched mode power supply. The gradient coil power supply comprises a switch unit (126) for each of the at least one coil element. The gradient coil power supply further comprises a current charger (128) for supplying current to each switch unit. The gradient coil power supply further comprises a modulator (124) for modulating each switch unit, wherein the gradient coil power supply further comprises a gradient controller (130) for controlling the modulation of each modulator. The modulator of each of the at least one coil element is attached to the at least one structural support. The switch unit of each of the at least one coil element is attached to the at least one structural support.

### FIELD OF THE INVENTION

The invention relates to magnetic resonance imaging, in particular to magnetic gradient coils for magnetic resonance imaging

### BACKGROUND OF THE INVENTION

A large static magnetic field is used by Magnetic Resonance Imaging (MRI) scanners to align the nuclear spins of atoms as part of the procedure for producing images within the body of a patient. This large static magnetic field is referred to as the BO field or the main magnetic field.

One method of spatially encoding the is to use magnetic field gradient coils. Typically there are three coils which are used to generate three different gradient magnetic fields in three different orthogonal directions.

During an MRI scan, Radio Frequency (RF) pulses generated by one or more transmitter coils cause a called B1 field. Additionally applied gradient fields and the B1 field do cause perturbations to the effective local magnetic field. RF signals are then emitted by the nuclear spins and detected by one or more receiver coils. These RF signals are used to construct the MR images. These coils can also be referred to as antennas.

Euorpean Patent Application EP 2 910 965 A1 discloses a multi-channel switching system for a MRI gradient coil system, comprising: a plurality of N_{switch} analog switches to connect a plurality of Nₑₗₑₘₑₙₜ coil elements, whereby said switches and coil elements form a plurality of N_{channel} electrical channels each driven by a gradient power amplifier; a distribution board to generate control signals for each of the switches; a digital controller providing the command code to the distribution board through a communication bus; and a power delivery system to power each of N_{switch} switches, is characterized in that the number N_{channel} of channels controlled by the power amplifiers is smaller than the number N_{switch} of switches N_{channel}<N_{switch}, whereby said switches are connected in series, in parallel or in a bridge configuration, that the number N_{channel} of channels controlled by the power amplifiers is smaller than the number Nₑₗₑₘₑₙₜ of coil elements in the coil system N_{channel}<Nₑₗₑₘₑₙₜ, whereby current in every of the coil elements can be switched to flow in either positive or negative direction or to bypass the respective coil element, and that the power to the N_{switch} elements is delivered via a smaller amount of N_{power} power lines, such that N_{power}<N_{switch} by means of a power distribution system providing floating power to each of the said switches. This allows to electrically connect matrix coil elements dynamically within a pulse sequence to generate dynamically switched magnetic field profiles, and therefore reduce the number of gradient power amplifiers, gradient cables and power supplies needed.

The conference proceeding Harris et. al., “A new approach to shimming: The dynamically controlled adaptive current network,” Proc. Intl. Soc. Mag. Reson. Med. 21 (2013), p. 0011, http://cds.ismrm.org/protected/13MProceedings/files/0011.PDF, discloses a magnetic shim coil with a rectangular mesh pattern, consisting of 48 nodes, was distributed over an acrylic cylindrical former with copper tape. HEXFET MOSFET photovoltaic relays were soldered between selective node connections, providing an open or closed variability for the current path between two conjoining nodes. The node connections selected to have MOSFET control were chosen to allow two distinct field profiles: an offset field shift and a z-gradient field. Single current input and output wires were connected to opposite ends of the shim coil. The coil was placed within a 3 T Siemens Tim Trio system and field maps were acquired in an ‘offset-field-mode’ and ‘gradient-mode.’

### SUMMARY OF THE INVENTION

The invention provides for a magnetic resonance imaging system, a method, and a computer program product in the independent claims. Embodiments are given in the dependent claims.

Embodiments of the invention may have a magnetic field gradient coil assembly that is supplied current by a switched mode power supply. The modulators and switching units are attached to or disposed on a structural support. This may enable a lower weight and less expensive magnetic resonance imaging system. Additionally, such an arrangement can be repeated many times in the magnetic field gradient coil. In some examples the gradient coil for each direction may have multiple coil elements which have their current individually controlled. This may enable easy shimming or adjustment of the gradient magnetic fields.

In one aspect, the invention provides for a magnetic resonance imaging system. The magnetic resonance imaging system comprises a magnet assembly for generating a main magnetic field within an imaging zone. A magnetic assembly may be a magnet for generating the main magnetic field. The magnet assembly may also comprise other components. For example the magnet assembly may comprise heating or cooling elements. The magnet assembly may also comprise a case or other components. In one example the magnet assembly comprises an integral unit and all of the components which surround the magnet.

The magnetic resonance imaging system further comprises a magnetic field gradient coil assembly for generating a spatial gradient magnetic field within the imaging zone. The magnetic field gradient coil assembly can also be referred to as the magnetic field gradient coils or simply gradient coils. The magnetic field gradient coil assembly comprises at least one structural support. Each of the at least one structural support comprises at least one coil element. The structural support may for instance be made of material in which the at least one coil element is attached to or is embedded within. The magnetic resonance imaging system further comprises a gradient coil power supply for supplying current to the magnetic field gradient coil assembly. The gradient coil power supply can also be referred to as the magnetic field gradient coil power supply. The gradient coil power supply is a switched mode power supply. The switched mode power supply may also be referred to as a switch or switching power supply. The gradient coil power supply comprises a switch unit for each of the at least one coil element.

The gradient coil power supply further comprises a current charger for supplying current to each switch unit. The current charger is essentially a current source. The switch unit may be configured for switching the current supplied by the current charger. The gradient coil power supply further comprises a modulator for modulating each switch unit. The gradient coil power supply further comprises a gradient controller for controlling the modulation of each modulator. The modulator of each of the at least one coil element is attached to or disposed on the at least one structural support. The switch of each of the at least one coil element is attached to or disposed on the at least one structural support.

In the gradient coil power supply the switch unit supplies current to each of the coil elements. The current charger supplies current to each of the switching units. The modulator is then used to control or modulate the switch unit.

Having the modulator and the switch unit adjacent to each coil may have several different benefits. It may allow collective cooling of the switch unit and the coil elements. It also reduces the distance that the modulated current needs to travel to reach the coil elements. The modulator is also placed next to the switching unit. This may make it easier to shield the connection between the switch unit and the modulator. It may also reduce the need or requirement of shielding the connection between the modulator and the switch unit.

In brief, the present invention concerns a magnetic resonance examination system with a gradient coil assembly. The gradient coil assembly comprises one or more coil elements. The coil elements are independently from each other driven by modulator driven switches. The modulators and switches are disposed on (attached to) the structural support of the gradient coil element. That is the modulators and switches are disposed on the structural support (e.g. the coil former) that also holds the electrical gradient coil conductors. In this way the modulators and switches can be placed close to the coil element(s). This allows for collective cooling of the coil element, switch and modulator. Also radio frequency shielding of the modulator and switch is made simpler.

Each switch unit is connected to a coil element. The switch element can for example be a PWM or PDM modulator.

The switch unit can for example be a MOSFET or insulated gate bipolar transistor. In other examples the switch unit may also be a GaN on silicone or siliconcarbit switch.

In another embodiment, the current charger could be a single unit which is supplied for all switching units. In other examples the current charger may be multiple units. There for instance may be more than one current charger and they each supply one or more of the switch units.

In another embodiment, the current charger could be a capacitor gang or bank that may be charged up before use. This may be beneficial because it may reduce the strain or power requirements for the magnetic resonance imaging system. The capacitors can be charged over a period of time.

In another embodiment, the current charger could also be one or more batteries. Non-magnetic batteries, such as, LiPO could be used.

In another embodiment, the batteries may incorporate a smart battery management system. The battery could for example be a smart battery that is able to monitor various parameter such as the current charge, supplied current, voltage, and state of health of battery cells. The battery might also be able to communicated with the magnetic resonance imaging system via a bus interface such as a System Management Bus. This may allow the battery to stop the magnetic resonance imaging system if the charge stored by the battery is insufficient.

In another embodiment, the current charger comprises a battery any a capacitor gang or bank. Before use, the battery may be used to charge the capacitor gang. This may be advantageous because by charging the capacitors a battery with a lower current rating may be used.

In another embodiment, the modulator is controlled via a wire, a twisted pair of wires, an optical system such as a fiber optic connection, or a wireless system. A wireless system may include a Wi-Fi or Bluetooth connection.

In another embodiment, the gradient controller could be mounted on the magnet assembly or could be with a computer controller that controls the overall magnetic resonance imaging system.

In another embodiment, the magnetic resonance imaging system further comprises a memory for storing machine-executable instructions and pulse sequence commands. The magnetic resonance imaging system further comprises a processor for controlling the magnetic resonance imaging system. Execution of the machine-executable instructions causes the processor to control the magnetic resonance imaging system using the pulse sequence commands.

Controlling the magnetic resonance imaging system with the pulse sequence commands causes it to acquire the magnetic resonance imaging data. Execution of the machine-executable instructions further cause the processor to reconstruct a magnetic resonance image using the magnetic resonance imaging data. The pulse sequence commands may be used to control the magnetic resonance imaging system according to a particular magnetic resonance imaging protocol. The magnetic resonance image may be reconstructed from the magnetic resonance imaging data using the same magnetic resonance imaging protocol.

In some embodiments, the pulse sequence commands may contain commands or controls for the gradient controller to control the flow of current to particular coil elements. In other embodiments, the pulse sequence commands only specify a particular gradient field that is desired to be achieved by the gradient coil power supply. In this case the gradient controller may receive the command for a particular gradient field and then convert it into commands for controlling each of the modulators.

In another embodiment, the pulse sequence commands are for acquiring the magnetic resonance data according to a zero echo time magnetic resonance imaging protocol. The magnetic resonance image is reconstructed according to the zero echo time magnetic resonance imaging protocol. This embodiment may be beneficial because the combination of having the modulator and the switch unit on the structural support may provide for a compact and inexpensive magnetic resonance imaging system. The zero echo time magnetic resonance imaging protocols typically require lower gradient coil fields than is required for conventional magnetic resonance imaging. The combination of the magnetic field gradient coil assembly and gradient coil power supply as described above with the zero echo time magnetic resonance imaging protocol may enable a very easy to use and inexpensive magnetic resonance imaging system to be constructed.

In another embodiment, execution of the machine-executable instructions further cause the processor to reconstruct a pseudo radiographic image using the magnetic resonance image. This may be done using the zero echo time pulse sequence commands. This may have the benefit of providing for a magnetic resonance imaging system which can be used to generate pseudo radiographic images at a reasonable cost. The use of the above described magnetic field gradient coil assembly and gradient coil power assembly may enable a system to be constructed which is inexpensive and transportable.

A pseudo x-ray or pseudo CTU or computer tomography scan are two examples of pseudo radiographic images.

In another embodiment, the current charger is attached to the magnet assembly.

In some examples, the controls for the modulators and also the leads or connectors from the current charger to the switch units may be provided on a ring around the magnetic field gradient coil assembly. This may provide for an efficient means of coupling such things as power and cooling for the magnetic field gradient coil assembly.

In another embodiment, the at least one coil element is multiple coil elements. The magnetic field gradient coil is configured for generating a gradient magnetic field in one or more directions. The magnetic field gradient coils comprise at least two coil elements selected from the multiple coil elements for each of the at least one direction. This embodiment may be beneficial as this enables the fine tuning of the gradient coils. Factors such as the temperature of the coil elements may affect the actual magnetic field generated by a particular coil element. If a gradient coil for a particular direction is broken into two more pieces it may be possible to adjust the amount of current that each portion of the gradient coil for that particular direction is generating. This may enable the generation of more accurate or uniform gradient fields. This may essentially allow shimming or adjustment of the gradient field in each direction. This can change for such things as temperature changes or changes in geometry of the coil.

In another embodiment, the magnetic resonance imaging system further comprises at least one gradient coil sensor. The gradient coil controller is configured for adjusting the current supply into each of the at least two coil elements using the at least one gradient coil sensor in a feedback control loop. This may be beneficial because the user can set a desired magnetic field strength or equivalent current and the gradient coil power supply and magnetic field gradient coil assembly will be self-correcting.

In another embodiment, the at least one gradient coil sensor comprises a current sensor on each of the at least two coil elements.

In another embodiment, the at least one gradient coil sensor comprises at least one magnetic field sensor within the imaging zone.

In another embodiment, the at least one gradient coil sensor comprises at least one magnetic field sensor attached to a subject support.

In another embodiment, the gradient coil sensor comprises at least one magnetic field sensor attached to the magnet assembly.

In another embodiment, the at least one gradient coil sensor comprises at least one magnetic field sensor attached to the at least one structural support.

The use of a current sensor and/or a magnetic field sensor may enable real time correction of the desired magnetic gradient field.

In another embodiment, the at least one structural support comprises any one of the following: a circuit board, a FR4 board, a non-planar circuit board, a flexible circuit board, an asymmetric circuit board, and combinations thereof.

In another embodiment, the magnetic field gradient coil is a split magnetic field gradient coil with a gap. The gradient coil power supply is located at least partially within the gap. For example, the modulators and/or the switch unit could be located within the gap. This may have the advantage of making the magnetic field gradient coil assembly more compact.

In another embodiment, the gradient coil power supply is a non-linear amplifier. When constructing the gradient coil power supply typically expensive linear amplifiers are used so that the accurate gradient coil field can be controlled and generated. However, embodiments may enable the use of a less expensive non-linear amplifier.

In another embodiment, the non-linear amplifier is combined with the above embodiments of the magnetic resonance imaging system further comprising at least one gradient coil sensor. This may allow accurate use of a less expensive non-linear amplifier.

In another embodiment, the magnetic resonance imaging system comprises a gradient coil cooling system. The gradient coil cooling system is configured for cooling the at least one coil element and the switch unit of the at least one coil element. This may be a cost effective and efficient means of cooling both units. This may result in a reduced cost and/or weight of the magnetic resonance imaging system.

In another embodiment, the magnetic resonance imaging system further comprises a local RF shield for each modulator. Each local RF shield is attached to the at least one structural support. This may be beneficial because the gradient coil may not need to be shielded. Only shielding the modulator may result in a system that functions properly but at a reduced cost.

In another embodiment, the modulator is controlled via any one of the following: a fiber optic, a wireless communication link, a Bluetooth connection, a Wi-Fi connection, and a wired connection. The use of the wireless communication link, the Bluetooth connection, and the Wi-Fi connection may have the advantage that there are fewer wires which need to be run into the bore of the magnet. This may have one or more of the following advantages: reduce the weight of the magnetic resonance imaging system, reduce the effect of cross talk on the modulator, reduce the number of electrical connections necessary, and may increase the reliability of the system due to a reduced number of mechanical connections.

In another aspect, the invention provides for a computer program product comprising machine-executable instructions for execution by a processor controlling a magnetic resonance imaging system. The magnetic resonance imaging system comprises a magnet assembly for generating a main magnetic field within an imaging zone. The magnetic resonance imaging system further comprises a magnetic field gradient coil assembly for generating a spatial gradient magnetic field within the imaging zone. The magnetic field gradient coil assembly comprises at least one structural support. Each of the at least one structural support comprises at least one coil element.

The magnetic resonance imaging system further comprises a gradient coil power supply for supplying current to the magnetic field gradient coil assembly. The gradient coil power supply is a switched mode power supply. The gradient coil power supply comprises a switch unit for each of the at least one coil elements. The gradient coil power supply further comprises a current charger for supplying current to each switch unit. The gradient coil power supply further comprises a modulator for modulating each switch unit.

The gradient coil power supply further comprises a gradient controller for controlling the modulation of each modulator. The modulator of each of the at least one coil element is attached to or disposed on the at least one structural support. The switch unit of each of the at least one coil element is attached to or dipsosed on the at least one structural support.

Execution of the machine-executable instructions causes the processor to control the magnetic resonance imaging system to acquire the magnetic resonance data by controlling it using the pulse sequence commands. Execution of the machine-executable instructions further cause the processor to reconstruct a magnetic resonance image using the magnetic resonance imaging data.

In another aspect, the invention provides for a method of controlling the magnetic resonance imaging system. The magnetic resonance imaging system comprises a magnet assembly for generating a main magnetic field within an imaging zone. The magnetic resonance imaging system further comprises a magnetic field gradient coil assembly for generating a spatial gradient magnetic field within the imaging zone. The magnetic field gradient coil assembly comprises at least one structural support. Each of the at least one structural support comprises at least one coil element.

The magnetic resonance imaging system further comprises a gradient coil power supply for supplying current to the magnetic field gradient coil assembly. The gradient coil power assembly is a switched mode power supply. The gradient coil power supply comprises a switch unit for each of the at least one coil element. The gradient coil power supply further comprises a current charger for supplying current to each switch unit. The gradient coil power supply further comprises a modulator for modulating each switch unit.

The gradient coil power supply further comprises a gradient controller for controlling the modulation of each modulator. The modulator of each of the at least one coil element is attached to or disposed on the at least one structural support. The switch unit of each of the at least one coil element is attached to or disposed on the at least one structural support. The method comprises controlling the magnetic resonance imaging system using the pulse sequence commands to acquire the magnetic resonance data. The method further comprises reconstructing a magnetic resonance image using magnetic resonance data.

It is understood that one or more of the aforementioned embodiments of the invention may be combined as long as the combined embodiments are not mutually exclusive.

As will be appreciated by one skilled in the art, aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer executable code embodied thereon.

Any combination of one or more computer readable medium(s) may be utilized. The computer readable medium may be a computer readable signal medium or a computer readable storage medium. A ‘computer-readable storage medium’ as used herein encompasses any tangible storage medium which may store instructions which are executable by a processor of a computing device. The computer-readable storage medium may be referred to as a computer-readable non-transitory storage medium. The computer-readable storage medium may also be referred to as a tangible computer readable medium. In some embodiments, a computer-readable storage medium may also be able to store data which is able to be accessed by the processor of the computing device. Examples of computer-readable storage media include, but are not limited to: a floppy disk, a magnetic hard disk drive, a solid state hard disk, flash memory, a USB thumb drive, Random Access Memory (RAM), Read Only Memory (ROM), an optical disk, a magneto-optical disk, and the register file of the processor. Examples of optical disks include Compact Disks (CD) and Digital Versatile Disks (DVD), for example CD-ROM, CD-RW, CD-R, DVD-ROM, DVD-RW, or DVD-R disks. The term computer readable-storage medium also refers to various types of recording media capable of being accessed by the computer device via a network or communication link. For example a data may be retrieved over a modem, over the internet, or over a local area network. Computer executable code embodied on a computer readable medium may be transmitted using any appropriate medium, including but not limited to wireless, wire line, optical fiber cable, RF, etc., or any suitable combination of the foregoing.

A computer readable signal medium may include a propagated data signal with computer executable code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

‘Computer memory’ or ‘memory’ is an example of a computer-readable storage medium. Computer memory is any memory which is directly accessible to a processor. ‘Computer storage’ or ‘storage’ is a further example of a computer-readable storage medium. Computer storage may be any volatile or non-volatile computer-readable storage medium.

A ‘processor’ as used herein encompasses an electronic component which is able to execute a program or machine executable instruction or computer executable code. References to the computing device comprising “a processor” should be interpreted as possibly containing more than one processor or processing core. The processor may for instance be a multi-core processor. A processor may also refer to a collection of processors within a single computer system or distributed amongst multiple computer systems. The term computing device should also be interpreted to possibly refer to a collection or network of computing devices each comprising a processor or processors. The computer executable code may be executed by multiple processors that may be within the same computing device or which may even be distributed across multiple computing devices.

Computer executable code may comprise machine executable instructions or a program which causes a processor to perform an aspect of the present invention. Computer executable code for carrying out operations for aspects of the present invention may be written in any combination of one or more programming languages, including an object oriented programming language such as Java, Smalltalk, C++ or the like and conventional procedural programming languages, such as the C programming language or similar programming languages and compiled into machine executable instructions. In some instances the computer executable code may be in the form of a high level language or in a pre-compiled form and be used in conjunction with an interpreter which generates the machine executable instructions on the fly.

The computer executable code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described with reference to flowchart illustrations and/or block diagrams of methods, apparatus (systems) and computer program products according to embodiments of the invention. It is understood that each block or a portion of the blocks of the flowchart, illustrations, and/or block diagrams, can be implemented by computer program instructions in form of computer executable code when applicable. It is further understood that, when not mutually exclusive, combinations of blocks in different flowcharts, illustrations, and/or block diagrams may be combined. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

A ‘user interface’ as used herein is an interface which allows a user or operator to interact with a computer or computer system. A ‘user interface’ may also be referred to as a ‘human interface device.’ A user interface may provide information or data to the operator and/or receive information or data from the operator. A user interface may enable input from an operator to be received by the computer and may provide output to the user from the computer. In other words, the user interface may allow an operator to control or manipulate a computer and the interface may allow the computer indicate the effects of the operator's control or manipulation. The display of data or information on a display or a graphical user interface is an example of providing information to an operator. The receiving of data through a keyboard, mouse, trackball, touchpad, pointing stick, graphics tablet, joystick, gamepad, webcam, headset, pedals, wired glove, remote control, and accelerometer are all examples of user interface components which enable the receiving of information or data from an operator.

A ‘hardware interface’ as used herein encompasses an interface which enables the processor of a computer system to interact with and/or control an external computing device and/or apparatus. A hardware interface may allow a processor to send control signals or instructions to an external computing device and/or apparatus. A hardware interface may also enable a processor to exchange data with an external computing device and/or apparatus. Examples of a hardware interface include, but are not limited to: a universal serial bus, IEEE 1394 port, parallel port, IEEE 1284 port, serial port, RS-232 port, IEEE-488 port, bluetooth connection, wireless local area network connection, TCP/IP connection, ethernet connection, control voltage interface, MIDI interface, analog input interface, and digital input interface.

A ‘display’ or ‘display device’ as used herein encompasses an output device or a user interface adapted for displaying images or data. A display may output visual, audio, and or tactile data. Examples of a display include, but are not limited to: a computer monitor, a television screen, a touch screen, tactile electronic display, Braille screen, Cathode ray tube (CRT), Storage tube, Bi-stable display, Electronic paper, Vector display, Flat panel display, Vacuum fluorescent display (VF), Light-emitting diode (LED) display, Electroluminescent display (ELD), Plasma display panel (PDP), Liquid crystal display (LCD), Organic light-emitting diode display (OLED), a projector, and Head-mounted display.

Medical imaging data is defined herein as two or three dimensional data that has been acquired using a medical imaging system. A medical imaging system is defined herein as a apparatus adapted for acquiring information about the physical structure of a patient and construct sets of two dimensional or three dimensional medical imaging data. Medical imaging data can be used to construct visualizations which might be useful for diagnosis by a physician. This visualization can be performed using a computer.

Magnetic Resonance (MR) data is defined herein as being the recorded measurements of radio frequency signals emitted by atomic spins using the antenna of a magnetic resonance apparatus during a magnetic resonance imaging scan. Magnetic resonance data is an example of medical imaging data. A Magnetic Resonance (MR) image is defined herein as being the reconstructed two or three dimensional visualization of anatomic data contained within the magnetic resonance imaging data.

### BRIEF DESCRIPTION OF THE DRAWINGS

In the following preferred embodiments of the invention will be described, by way of example only, and with reference to the drawings in which:

FIG. 1 illustrates an example of a magnetic resonance imaging system;

FIG. 2 illustrates a further example of a magnetic resonance imaging system;

FIG. 3 shows a flow chart which illustrates a method of using the magnetic resonance imaging system of FIG. 1 or FIG. 2;

FIG. 4 illustrates a further example of a magnetic resonance imaging system;

FIG. 5 illustrates multiple coil elements;

FIG. 6 illustrates a closed feedback control loop for a modulator;

FIG. 7 illustrates an example of a magnetic field gradient coil assembly;

FIG. 8 illustrates a further example of a magnetic field gradient coil assembly;

FIG. 9 illustrates a further example of a magnetic field gradient coil assembly;

FIG. 10 illustrates a further example of a magnetic field gradient coil assembly; and

FIG. 11 shows a schematic of an example gradient coil power supply.

### DETAILED DESCRIPTION OF THE EMBODIMENTS

Like numbered elements in these figures are either equivalent elements or perform the same function. Elements which have been discussed previously will not necessarily be discussed in later figures if the function is equivalent.

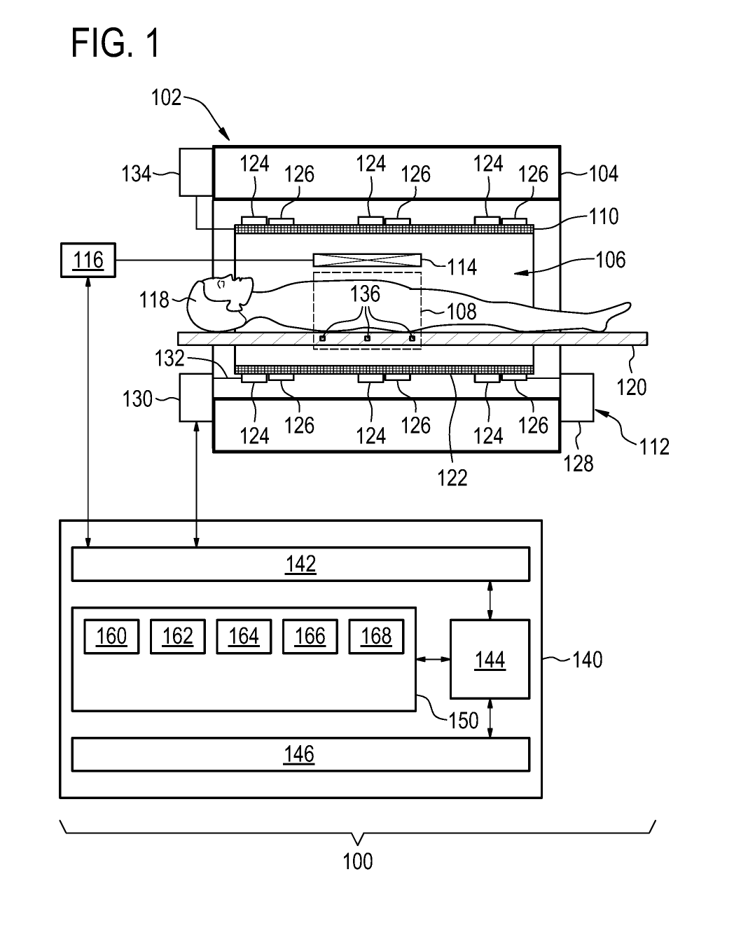

FIG. 1 illustrates an example of a magnetic resonance imaging system 100. The magnetic resonance imaging system comprises a magnet assembly 102 which comprises a magnet 104, which may be referred to as a main magnet. The magnet 104 is a superconducting cylindrical type magnet 104 with a bore 106 through it. The use of different types of magnets is also possible. Inside the cryostat of the cylindrical magnet, there is a collection of superconducting coils. Within the bore 106 of the cylindrical magnet 104 there is an imaging zone 108 where the magnetic field is strong and uniform enough to perform magnetic resonance imaging.

Within the bore 106 of the magnet there is also a set of magnetic field gradient coils 110 which is used for acquisition of magnetic resonance data to spatially encode magnetic spins within the imaging zone 108 of the magnet 104. The magnetic field gradient coils 110 are connected to a magnetic field gradient coil power supply 112. The magnetic field gradient coils 110 are intended to be representative. Typically magnetic field gradient coils 110 contain three separate sets of coils for spatially encoding in three orthogonal spatial directions. A magnetic field gradient power supply supplies current to the magnetic field gradient coils. The current supplied to the magnetic field gradient coils 110 is controlled as a function of time and may be ramped or pulsed.

Adjacent to the imaging zone 108 is a radio-frequency coil 114 for manipulating the orientation of magnetic spins within the imaging zone 108 and for receiving radio transmissions from spins also within the imaging zone 108. The radio frequency antenna may contain multiple coil elements. The radio frequency antenna may also be referred to as a channel or antenna. The radio-frequency coil 114 is connected to a radio frequency transceiver 116. The radio-frequency coil 114 and radio frequency transceiver 116 may be replaced by separate transmit and receive coils and a separate transmitter and receiver. It is understood that the radio-frequency coil 114 and the radio frequency transceiver 116 are representative. The radio-frequency coil 114 is intended to also represent a dedicated transmit antenna and a dedicated receive antenna. Likewise the transceiver 116 may also represent a separate transmitter and receiver. The radio-frequency coil 114 may also have multiple receive/transmit elements and the radio frequency transceiver 116 may have multiple receive/transmit channels.

Within the bore 106 of the magnet 104 there is a subject support 120 which supports the subject in the imaging zone 108. A region of interest 109 can be seen within the imaging zone 108.

The magnetic field gradient coils 110 comprise a structural support 122. In this example the individual coil elements are not shown but are embedded within the structural support 122. Shown on the structural support 122 are also a number of modulators 124 which are each connected to a switch unit 126. For each coil element there is a modulator 124 and a switch unit 126. The modulators 124 may each have a local radio frequency shield which is not shown in this Fig. The modulator 124 and the switch unit 126 may also be embedded or located within grooves or other depressions of the structural support 122. Each of the switch units 126 is connected to a current charger 128. The current charger 128 is shown as being attached to the magnet assembly 102. The magnetic resonance imaging system 100 is also shown as comprising a gradient controller 130. The gradient controller 130 controls the modulation of the modulators 124. In this example there is a connection 132 between the gradient controller 130 and each modulator 124. Also shown as being mounted on the magnet assembly 102 is a gradient coil cooling system 134. In some embodiments the gradient coil cooling system 134 may supply cooling fluid to individual coil elements as well as the switch unit 126 and/or the modulator 124.

In this example are also shown optional magnetic field sensors 136. In this example they are shown as being embedded in the subject support 120. They however may be located within the imaging zone 108. They may be used to measure the gradient field generated by the magnetic field gradient coils 110. The measurement with the magnetic field sensors 136 may be used to adjust the current to individual coil elements by the gradient controller 130. This may allow real time correction or shimming of the gradient fields.

The transceiver 116 and the gradient controller 130 are shown as being connected to a hardware interface 142 of a computer system 140. The computer system further comprises a processor 144 that is in communication with the hardware system 142, memory 150, and a user interface 146. The memory 150 may be any combination of memory which is accessible to the processor 144. This may include such things as main memory, cached memory, and also non-volatile memory such as flash RAM, hard drives, or other storage devices. In some examples the memory 150 may be considered to be a non-transitory computer-readable medium. The memory 150 is shown as storing machine-executable instructions 160 which enable the processor 144 to control the operation and function of the magnetic resonance imaging system 100. The memory 150 is further shown as containing pulse sequence commands 162. Pulse sequence commands as used herein encompass commands or a timing diagram which may be converted into commands which are used to control the functions of the magnetic resonance imaging system 100 as a function of time. Pulse sequence commands are the implementation of the magnetic resonance imaging protocol applied to a particular magnetic resonance imaging system 100.

The pulse sequence commands 162 may be in the form of commands which the processor 144 sends to the various components of the magnetic resonance imaging system 100 or they may be data or Meta data which is converted into commands that the processor 144 uses to control the magnetic resonance imaging system 100.

The memory 150 is further shown as containing magnetic resonance data 164 that was acquired by controlling the magnetic resonance imaging system 100 with the pulse sequence commands 162. The memory 150 is further shown as containing a magnetic resonance image 166 that was reconstructed from the magnetic resonance data 164. In some examples the magnetic resonance imaging system 100 may use pulse sequence commands that acquire magnetic resonance data according to a zero echo time magnetic resonance imaging protocol in which case the magnetic resonance image 166 may contain detailed images of bone or other hard tissue of the subject 118. In this case the machine-executable instructions 160 can also be programmed to cause the processor 144 to create a pseudo radiographic image 168 from the magnetic resonance image 166.

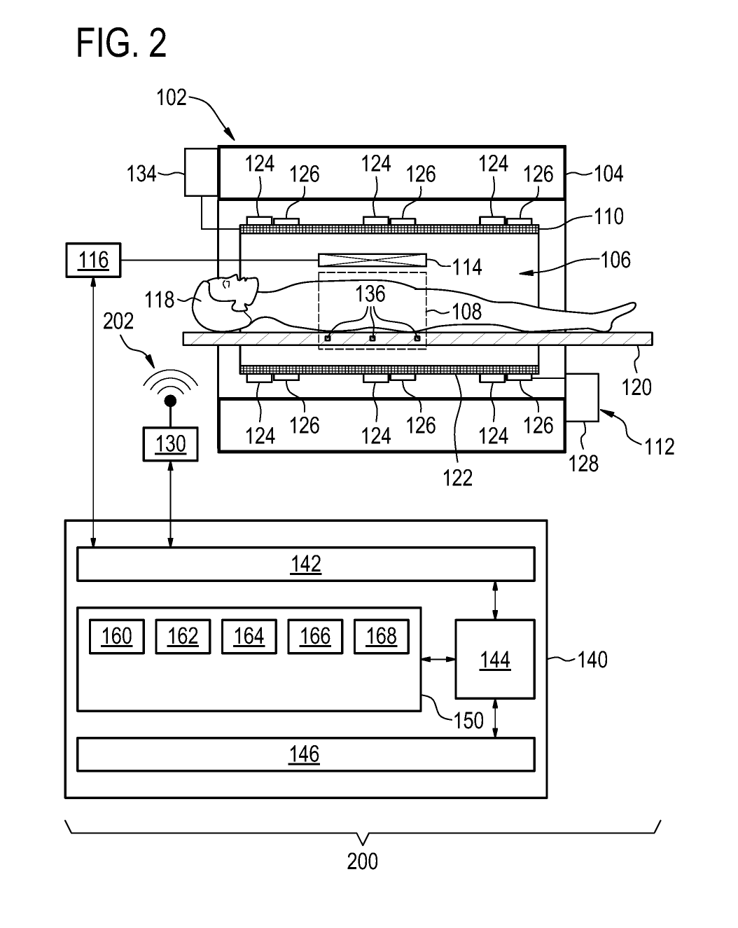

FIG. 2 shows a further example of a magnetic resonance imaging system 200. The example in FIG. 2 is similar to that shown in FIG. 1 except there is no connection 132 between the gradient controller 130 and each of the modulators 124. In this case the gradient controller 130 is configured to form a radio frequency connection 202 with each of the modulators 124. For example the radio frequency connection may be a radio signal, it may be a Bluetooth connection, it may be a Wi-Fi connection, or some other radio frequency communication protocol. The use of the radio frequency connection 202 may be beneficial because it may simplify the number of connections and also the space consumed by connections when constructing the magnetic resonance imaging system 200. This may provide for more room within the bore 106 for subjects 118. In the example shown in FIG. 2 the magnetic field sensors 136 may have a wired connection or may also transmit wireless data to the gradient controller 130.

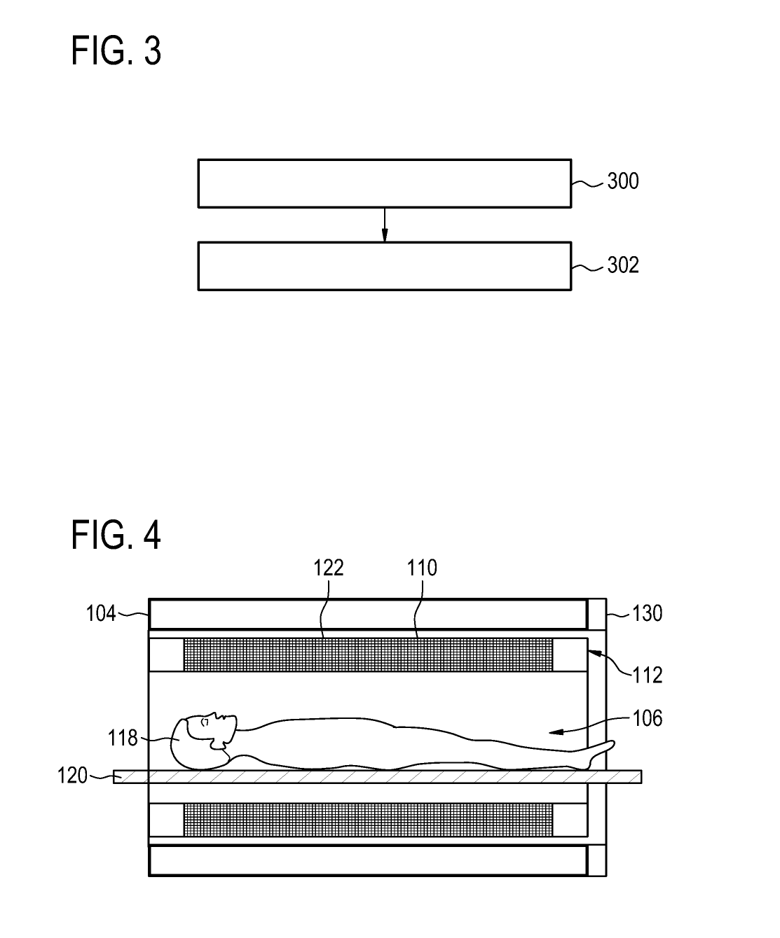

FIG. 3 shows an example of a method of controlling the magnetic resonance imaging system 100 of FIG. 1 or the magnetic resonance imaging system 200 of FIG. 2. First in step 300 the processor 144 controls the magnetic resonance imaging system 100 with the pulse sequence commands 162. This causes the magnetic resonance imaging system 100 to acquire the magnetic resonance data 164. Next in step 302 the processor 144 uses the machine-executable instructions 160 to reconstruct the magnetic resonance image 166 using the magnetic resonance data 164. In some instances the method may continue and the processor may reconstruct pseudo radiographic images 168 using the magnetic resonance image 166. Also in some further examples the magnetic resonance image 166 and/or the pseudo radiographic image 168 may be displayed on the user interface 146.

Zero Echo Time (ZTE) Magnetic Resonance Imaging potentially enables a dramatic reduction in the cost of an MR scanner, retaining sufficient imaging capabilities to satisfy basic diagnostic requirements. If all possible cost savings are realized, it is expected that the bill of materials, siting and operation costs of an MRI can be reduced by 30 to 50 percent. In addition, a scanner based on this technology would be completely silent and consume much less electrical power than a conventional MRI system. It is the objective of this project to generate system concept options for such a scanner, including a more accurate assessment of possible cost savings, development risks, required development resources and time to market.

An optimized ZTE scanner could constructed so as to acquire CT-like images without radiation at approximately the same or even lower cost compared with a CT scanner. One feature of ZTE imaging is the lower required gradient field strength allowing gradient coils without active shielding requirements. Gradient amplifiers are located in a separate technical room thus requiring gradient cables and filtering. Examples could locate the gradient amplifier directly or partly on the gradient coil allowing shared cooling and cost reduction for low cost ZTE MRI.

Examples may solve one or more of the following problems:

Separate remote gradient amplifier

Cable and filtering,

mechanical housing of gradient amplifier,

remote technical room,

need for cost reduction for low cost ZTE MRI system, and

separate cooling for gradient coil and gradient amplifier

Some examples may combines gradient coil and gradient amplifier module for low cost mobile lightweight ZTE MRI system. Parts of the gradient switching electronics may be located on the gradient support. Individual gradient windings can be separately controlled, thus electrical connections between the windings can be omitted allowing more freedom in the design of the gradient coil.

Examples may have one or more of the following features:

The liquid/conduction cooling shared by gradient amplifier and gradient coil.

The gradient amplifier electronics is locally shielded to prevent spurious signal radiation from PCM gradient signal.

High power and digital optical control of gradient amplifier can be distributed on gradient coil and magnet shield.

FIG. 4 shows an example of a zero echo time magnetic resonance imaging system with a low power gradient coil and a directly integrated gradient amplifier 112. The gradient amplifier 112 may share the same cooling method with the gradient coil 110. In this Fig. the gradient controller 130 is shown as being distributed as a ring around the opening of the bore 106 of the magnet 110. The gradient amplifier 112 is also shown as being distributed in a similar fashion.

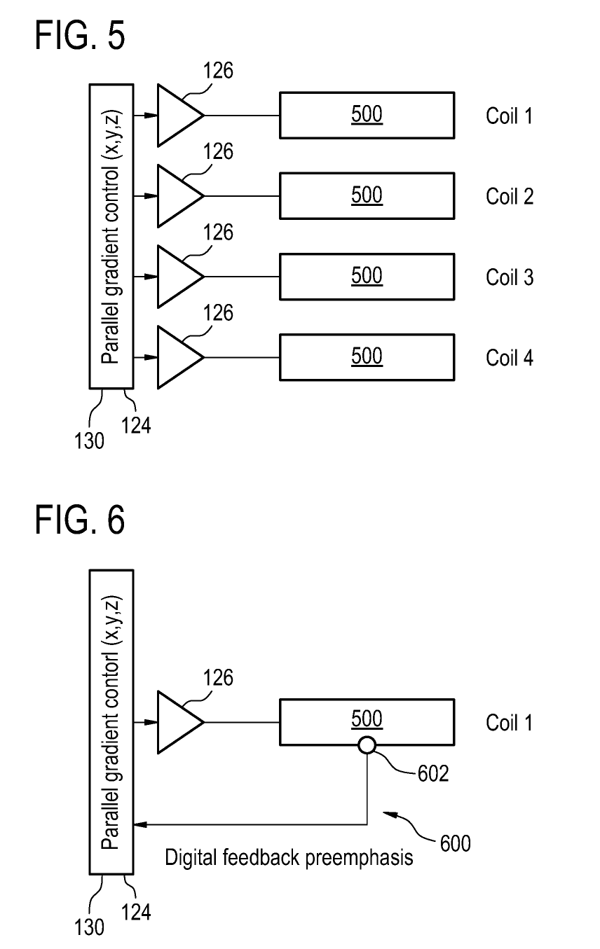

FIG. 5 shows how each individual coil gradient direction consists of separate winding blocks or coil elements 500. They are individually fed by separate amplifiers. The amplifiers comprise the switch units 126 which are controlled by the gradient controller 130 and modulators 124.

FIG. 6 illustrates how each coil element 500 could have an integrated feedback loop 600. A gradient coil sensor 602 may be either used to measure the current flowing through the coil element 500 or may be a magnetic field sensor. The measurements from this are fed back via control loop 600 to the gradient controller 130. In this way the current supplied to the coil element 500 can be adjusted in real time.

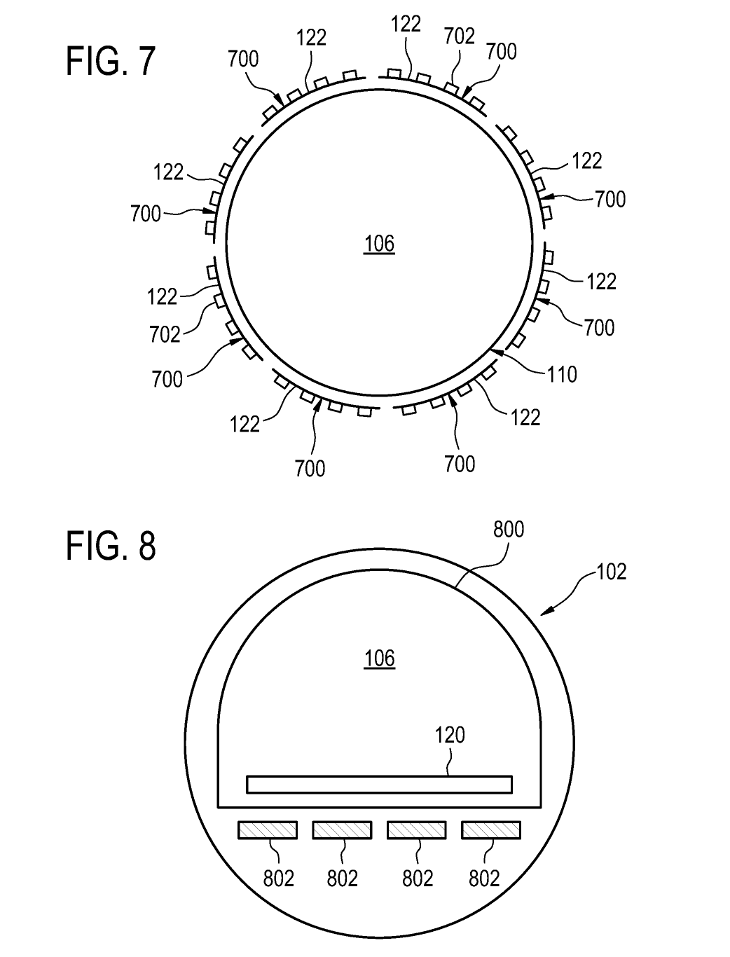

FIG. 7 shows an example of a gradient coil 110 which is cylindrical and has distributed local amplifiers. The gradient coil amplifier 110 has a number of structural supports 122 that also contain amplifier modules 700. The amplifier modules are shown as having a number of rectangles attached to them. The rectangles 702 are IGBT/MOSFET components which are used as the switching units.

FIG. 8 shows an example of a gradient amplifier which is located at the bottom of the gradient coil assembly. In FIG. 8 the magnet assembly 102 is depicted. The magnetic field gradient coil assembly 800 in this example is asymmetric. A patient support 120 is shown as being within the bore of the magnet 106. Below the patient support 120 are a number of gradient amplifier modules 802. These are attached to the modulators and switching units of the gradient coil 800.

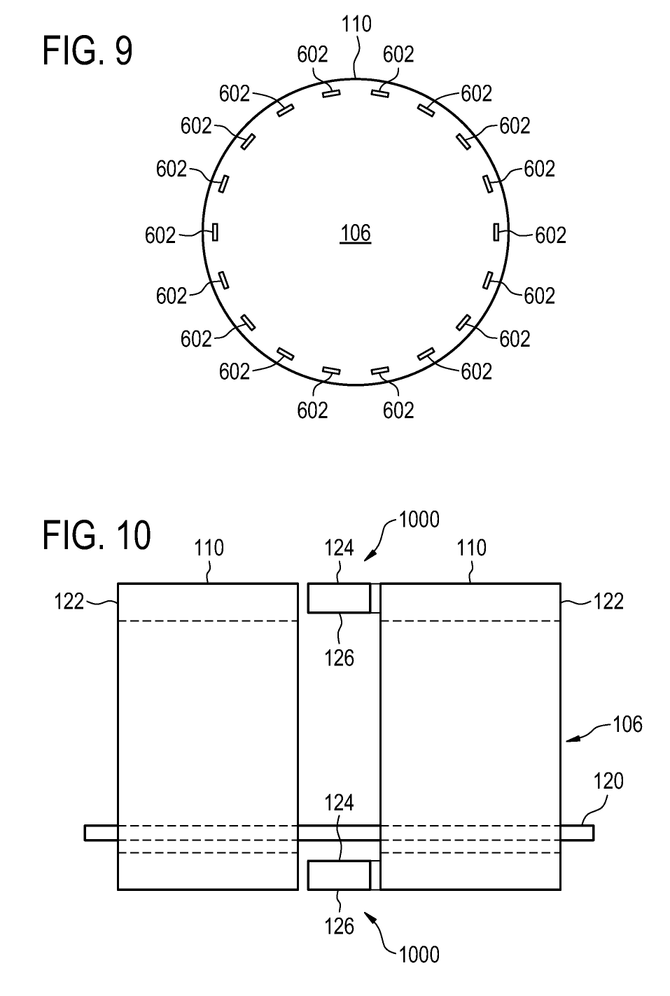

FIG. 9 shows a further example of the magnetic field gradient coil 110. It is a cylindrical assembly. In this example the gradient coil sensor 602 are distributed on the gradient coil 110.

FIG. 10 shows a further example of a magnetic field gradient coil 110. In this example it is a split gradient coil with a recess or a gap 1000 between the two portions. Within the gap 1000 is located the gradient amplifier and may consist of the modulator 124 and the switching unit 126. The modulator 124 and switching unit 126 may be attached to or disposed on the structural supports 122.

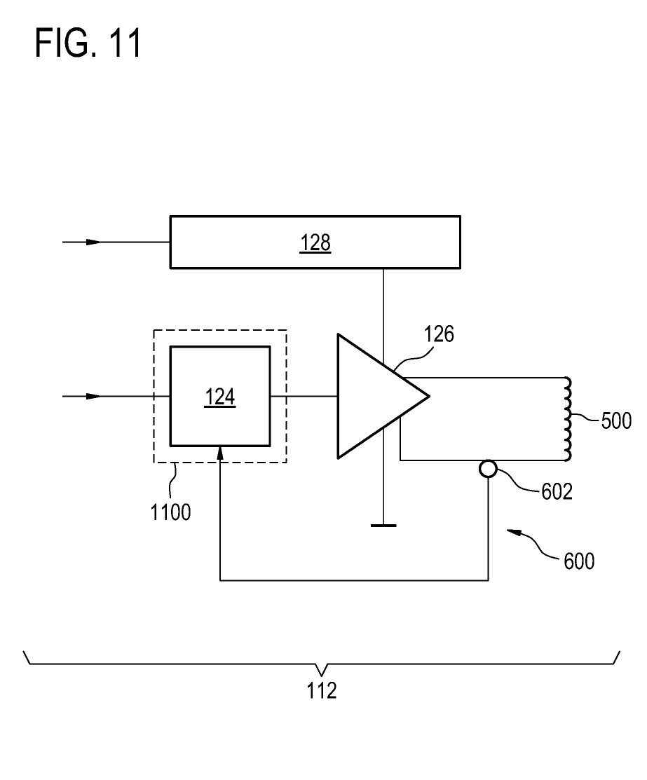

FIG. 11 shows an example of the magnetic field gradient coil power supply 112 as a schematic. Shown is a modulator 124 that is used to modulate or control a switch unit 126. The modulator 124 is shown as having a local RF shield 1100. The local RF shield 1100 may be mounted to the structural support. A current charger 128 which may be a current source such as a capacitor gang supplies current to the switch unit 126. The switch unit is then used to drive an individual coil element 500. A gradient coil sensor 602 which may be a current or a magnetic field sensor makes a measurement and this is used as a feedback loop 600 to the modulator 124. In this example the feedback 600 is shown as going to the modulator 124 but it also may be fed back in addition to or alternatively to the gradient controller.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measured cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

### LIST OF REFERENCE NUMERALS

100 magnetic resonance system
102 magnet assembly
104 main magnet
106 bore of magnet
108 imaging zone
109 region of interest
110 magnetic field gradient coils
112 gradient coil power supply
114 radio-frequency coil
116 transceiver
118 subject
120 subject support
122 structural support
124 modulator
126 switch unit
128 current charger
130 gradient controller
132 connection
134 gradient coil cooling system
136 magnetic field sensor
140 computer system
142 hardware interface
144 processor
146 user interface
150 computer memory
160 machine executable instructions
162 pulse sequence commands
164 magnetic resonance data
166 magnetic resonance image
168 pseudo radiographic image
200 magnetic resonance imaging system
202 radio frequency connection
300 control the magnetic resonance imaging system to acquire magnetic resonance data using the pulse sequence commands
302 reconstruct a magnetic resonance image using the magnetic resonance imaging data
500 coil element
600 feedback loop
602 gradient coil sensor
700 amplifier module
702 IGBT/MOSFET components
800 asymmetric magnetic field gradient coil
802 gradient amplifier modules
1000 gap
1100 local RF shield

1. A magnetic resonance imaging system comprising:
a magnet assembly for generating a main magnetic field within an imaging zone;
a magnetic field gradient coil assembly for generating a spatial gradient magnetic field within the imaging zone, wherein the magnetic field gradient coil assembly comprises at least one structural support, wherein each of the at least one structural support comprises at least one coil element;
a gradient coil power supply for supplying current to the magnetic field gradient coil assembly, wherein the gradient coil power supply is a switched mode power supply, wherein the gradient coil power supply comprises a switch unit for each of the at least one coil element, wherein the gradient coil power supply further comprises a current charger for supplying current to each switch unit, wherein the gradient coil power supply further comprises a modulator for modulating each switch unit, wherein the gradient coil power supply further comprises a gradient controller for controlling the modulation of each modulator, wherein the modulator of each of the at least one coil element is attached to the magnetic field gradient coil assembly's at least one structural support, and wherein the switch unit of each of the at least one coil element is attached to the magnetic field gradient coil assembly's at least one structural support,
a memory for storing machine executable instructions and pulse sequence commands,
a processor for controlling the magnetic resonance imaging system, wherein execution of the machine executable instructions further cause the processor to:
control to acquire magnetic resonance data using the pulse sequence commands; and
reconstruct a magnetic resonance image using the magnetic resonance imaging data, wherein the pulse sequence commands acquire the magnetic resonance data according to a zero echo time magnetic resonance imaging protocol, wherein the magnetic resonance image is reconstructed according to the zero echo time magnetic resonance imaging protocol; and
a gradient coil cooling system, wherein the gradient coil cooling system is configured for cooling the at least one coil element and the switch unit of the at least one coil element.

2. (canceled)

3. (canceled)

4. The magnetic resonance imaging system of claim 1, wherein execution of the machine executable instructions further cause the processor to construct a pseudo radiographic image using the magnetic resonance image.

5. The magnetic resonance imaging system of claim 1, wherein the at least one coil element is multiple coil elements, wherein the magnetic field gradient coil is configured for generating a gradient magnetic field in one or more directions, wherein the magnetic field gradient coils comprises at least two coil elements selected from the multiple coil elements for each of the at least one direction.

6. The magnetic resonance imaging system of claim 5, wherein the magnetic resonance imaging system further comprises at least one gradient coil sensor, wherein the gradient controller is configured for adjusting the current supplied to each of the at least two coil elements using the at least one gradient coil sensor in a feedback control loop.

7. The magnetic resonance imaging system of claim 6, wherein the at least one gradient coil sensor comprises any one of the following: a current sensor on each of the at least two coil elements, at least one magnetic field sensor within the imaging zone, at least one magnetic field sensor attached to a subject support, at least one magnetic field sensor attached to the magnet assembly, at least one magnetic field sensor attached to the at least one structural support, and combinations thereof.

8. The magnetic resonance imaging system of claim 1, wherein the at least one structural support comprises any one of the following: a circuit board, a FR4 board, a non-planar circuit board, a flexible circuit board, an asymmetric circuit board, and combinations thereof.

9. The magnetic resonance imaging system of claim 1, wherein the magnetic field gradient coil is a split magnetic field gradient coil with a gap, wherein the gradient coil power supply is located at least partially within the gap.

10. The magnetic resonance imaging system of claim 1, wherein the gradient coil power supply is a non-linear amplifier.

11. The magnetic resonance imaging system of claim 1, wherein the magnetic resonance imaging system, wherein the gradient coil cooling system is configured for cooling the at least one coil element and the switch unit of the at least one coil element.

12. The magnetic resonance imaging system of claim 1 further comprising a local RF shield for each modulator, wherein each local RF shield is attached to the at least one structural support.

13. The magnetic resonance imaging system of claim 1, wherein the modulator is controlled via any one of the following: a fiber optic, a wire, a wireless communication link, a Bluetooth connection, and a WiFi connection.

14. (canceled)

15. (canceled)

16. A magnetic resonance imaging system:
a magnet assembly for generating a main magnetic field within an imaging zone;
a magnetic field gradient coil assembly for generating a spatial gradient magnetic field within the imaging zone, wherein the magnetic field gradient coil assembly comprises at least one structural support, wherein each of the at least one structural support comprises at least one coil element;
a gradient coil power supply for supplying current to the magnetic field gradient coil assembly, wherein the gradient coil power supply is a switched mode power supply, wherein the gradient coil power supply comprises a switch unit for each of the at least one coil element, wherein the gradient coil power supply further comprises a current charger for supplying current to each switch unit, wherein the gradient coil power supply further comprises a modulator for modulating each switch unit, wherein the gradient coil power supply further comprises a gradient controller for controlling the modulation of each modulator, wherein the modulator of each of the at least one coil element is attached to the magnetic field gradient coil assembly's at least one structural support, and wherein the switch unit of each of the at least one coil element is attached to the magnetic field gradient coil assembly's at least one structural support, wherein the magnetic resonance imaging system further comprises:
a memory for storing machine executable instructions and pulse sequence commands,
a processor for controlling the magnetic resonance imaging system, wherein execution of the machine executable instructions further cause the processor to:
control the magnetic resonance imaging system to acquire magnetic resonance data using the pulse sequence commands; and
reconstruct a magnetic resonance image using the magnetic resonance imaging data, the pulse sequence commands are for acquiring the magnetic resonance data according to a zero echo time magnetic resonance imaging protocol, wherein the magnetic resonance image is reconstructed according to the zero echo time magnetic resonance imaging protocol, wherein the magnetic resonance imaging system further comprises a local RF shield for each modulator, wherein each local RF shield is attached to the at least one structural support.
